(19) United States
(12) Patent Application Publication
(10) Pub. No.: US 2007/0054474 A1
(43) Pub. Date: Mar. 8, 2007

(54) Crack-free III-V epitaxy on germanium on insulator (GOI) substrates

(76) Inventors: Clarence J. Tracy, Tempe, AZ (US); Eric S. Johnson, Scottsdale, AZ (US); Papu D. Maniar, Mesa, AZ (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/209,295

(22) Filed: Aug. 23, 2005

(51) Int. Cl. H01L 21/20

(52) U.S. Cl. 438/479

(57) ABSTRACT

A method of forming III-V epitaxy on a germanium-on-insulator (GOI) substrate having a bonded layer and a handle substrate begins with measuring a lattice parameter of the bonded layer at a first temperature. The lattice parameter of the bonded layer, which is a function of a coefficient of thermal expansion (CTE) of the handle substrate, is then calculated at an epitaxial growth temperature. An epitaxial composition is selected from a class of III-V material for epitaxial growth overlying the bonded layer, wherein the selected epitaxial composition is adjusted to have a lattice parameter that approximates the calculated lattice parameter of the bonded layer at the epitaxial growth temperature. An epitaxial layer can then be grown over the bonded layer with use of the adjusted epitaxial composition, producing a substantially defect-free III-V epitaxial layer. Furthermore, an improved defectivity is claimed when the epitaxial layer's CTE is approximately similar to that of the handle substrate.

### BACKGROUND

The present disclosure relates generally to semiconductors, and more particularly, to crack-free III-V epitaxy on germanium-on-insulator (GOI) substrates and method for forming the same.

Integration of III-V devices with germanium and silicon CMOS devices on the same substrate is based upon the use of germanium-on-insulator (GOI) wafers to serve as a template for subsequent III-V epi growth. GOI wafers include, for example, germanium on silicon dioxide on a silicon handle wafer.

In an effort to reduce the defectivity level in a gallium arsenide (GaAs) on germanium (Ge) bulk substrate process, indium (In) was added to the process to adjust the lattice constant thereof for a more perfect match. However, when this same one-and-a-half percent (1.5%) InGaAs epi was used for GOI substrates, it was quickly discovered that it does not work. There were two failure modes, both observed in optical microscope inspections. The first failure mode comprised a cross hatching of the epi, indicating serious defectivity. The second failure mode comprised actual delamination of the films at the germanium to silicon dioxide interface at the edges of the GOI wafer. In addition, subsequent device processing leads to delamination throughout the GOI wafer.

The delamination problem discussed above is believed to be caused by differences between the coefficient of thermal expansion (CTE) of silicon (Si), germanium (Ge), and gallium arsenide (GaAs). Whereas Ge and GaAs CTEs are closely matched, the CTE of Si is much smaller and thus the thick silicon handle wafer constrains the Ge expansion during heating for epi growth. The lattice parameter for 1.5% InGaAs does not match the constrained Ge and thus as the film grows, it exceeds the critical thickness and relaxes through defect formation. Then, upon cool down, the entire III-V epi and the Ge upon which it resides become tensile. Furthermore, if the thickness is great enough, then the strain energy exceeds the adhesion of the germanium to silicon dioxide interface. One cannot retune the InGaAs system to match the constrained Ge at growth temperature, and even if one could do so, the CTE difference remains and the system will become tensile and likely fail upon return to room temperature.

The growth of GaAs epi on bulk Ge is a known process, used for solar cells for space applications. In addition, the method of tuning the lattice constant of GaAs by adding In to better match bulk Ge is known. However, such a method does not face a CTE mismatch problem because the known method involves growing GaAs on a free standing Ge substrate.

The CTE mismatch between GaAs and silicon has been identified as a problem for direct growth of GaAs on silicon. However, because of the extreme lattice constant differences, it is not clear how to tune the lattice constant to grow defect free epi nor is there a single crystal to amorphous interface where adhesion is a concern.

AlGaInP and specifically Ga_{0.52}In_{0.48}P have been grown on GaAs and Ge substrates with an intervening buffer layer. These were lattice matched to GaAs and were chosen for their wide direct energy gaps in the III-V alloys for visible light emitters. However, they were not deposited directly on Ge, not deposited on GOI wafers, and not lattice matched to silicon constrained Ge at the growth temperature.

Turning now to FIG. 1, a cross-sectional view of a Germanium-On-Insulator (GOI) substrate 10 is shown, as known in the art. GOI substrate 10 includes a handle substrate 12 having a layer 14 bonded to the handle substrate 12 using a suitable method known in the art. In one example, handle substrate 12 includes a silicon wafer 16 having an oxide layer 18 disposed on a top surface of the silicon wafer 16. The bonded layer 14 is a thin layer of single crystal germanium having a thickness on the order of a few hundred nanometers, and more particularly, on the order of 100 nm.

FIG. 2 is a cross-sectional view of a GaAs epitaxial layer 22 grown on the GOI substrate 10 of FIG. 1, the GaAs epitaxial layer 22 having misfit dislocations 24. In one example, the GaAs layer 22 is formed on the surface of germanium layer 14 using a metal organic chemical vapor deposition (MOCVD) process as is known in the art. In FIG. 2, reference numeral 15 generally indicates an illustration of the lattice and the bonds between atoms of the Ge layer 14. In addition, reference numeral 23 generally indicates an illustration of the lattice parameter and the bonds between atoms of the epitaxy layer 22. Misfit dislocations are generally indicated by reference numeral 24. The misfit dislocations 24 originate at an interface between the Ge layer 14 and epitaxy layer 22. Such misfit dislocations 24 are caused by a mismatch of the lattice parameter of the material of layer 22 with the lattice parameter of the Ge of layer 14.

On the other hand, it is possible for an InGaAs epitaxial layer to be grown on a bulk Ge substrate with an absence of misfit dislocations. However, if the InGaAs epitaxial layer were grown on the Ge layer 14 of the GOI substrate 10, the resulting InGaAs epi layer would also include misfit dislocations due to lattice parameter mismatches between the epitaxial layer 22 and the Ge layer 14.

FIG. 3 is a phase contrast microscope image view 30 of an example of delamination in a thick (on the order of microns) epi structure having misfit dislocations, viewed from above a top surface of the epi structure. In image 30, the dark area indicated by reference numeral 32 represents an area that is completely missing of the epi stack. Regions 34 and 36 represent areas where the epi material has lifted, but not yet broken completely free, from the underlying layer or substrate.

Accordingly, it would be desirable to provide an improved epitaxial method for overcoming the problems in the art as discussed above.

### BRIEF DESCRIPTION OF THE DRAWINGS

The embodiments of the present disclosure are illustrated by way of example and not limited by the accompanying figures, in which like references indicate similar elements, and in which:

FIG. 1 is a cross-sectional view of a Germanium-On-Insulator (GOI) substrate as known in the art;

FIG. 2 is a cross-sectional view of a GaAs epitaxial layer grown on the GOI substrate of FIG. 1, the GaAs epitaxial layer having misfit dislocations as is known in the art;

FIG. 3 is a microscope image view of an example of delamination in a thick epi structure having a high concentration of misfit dislocations;

FIG. 4 is a cross-sectional view of a Ga_{0.53}In_{0.47}P epitaxial layer grown on a GOI substrate according to an embodiment of the present disclosure, wherein a lattice parameter of the Ga_{0.53}In_{0.47}P epitaxial layer is correctly matched to a lattice parameter of the germanium of the GOI substrate;

FIG. 5 is a table view of various coefficients of thermal expansion (a) and lattice parameters (a) at various temperatures according to one embodiment of the present disclosure;

FIG. 6 is a flow diagram view of the method of growing an epitaxial layer in the manufacturing of a semiconductor device according to an embodiment of the present disclosure; and

FIG. 7 is a cross-sectional view of an epitaxial layer and nucleation layer grown on a GOI substrate according to another embodiment of the present disclosure, wherein a lattice parameter of the epitaxial layer is correctly matched to a lattice parameter of the constrained germanium of the GOI substrate.

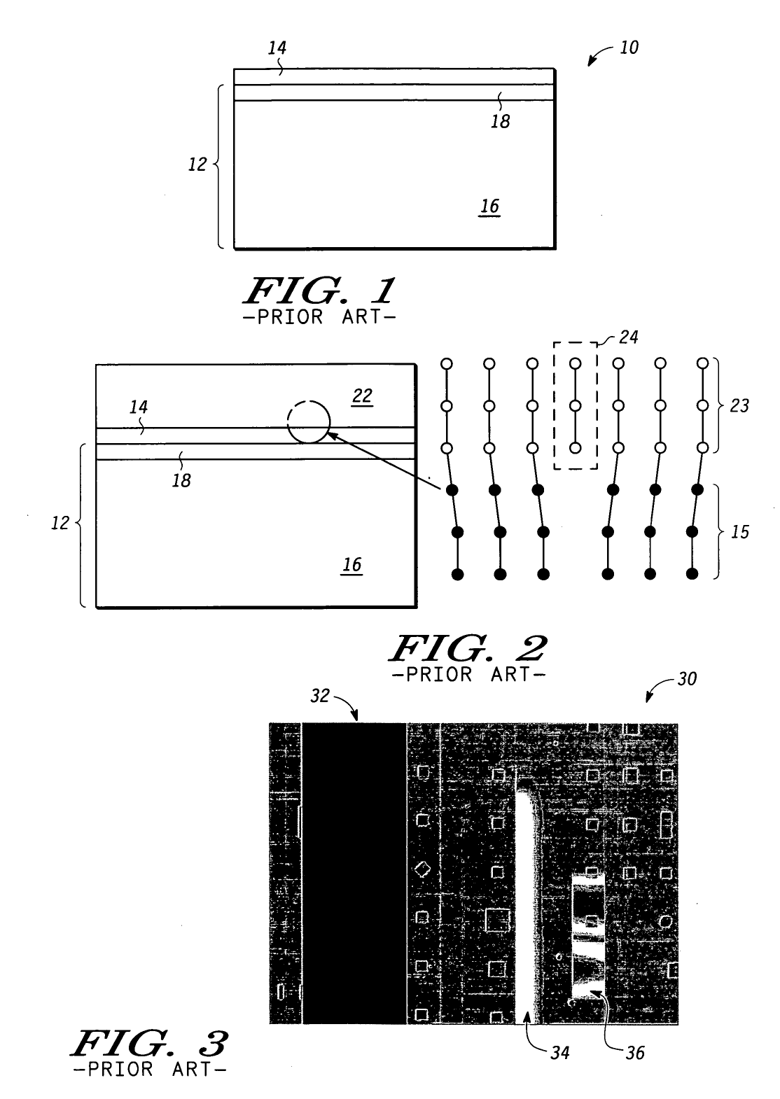

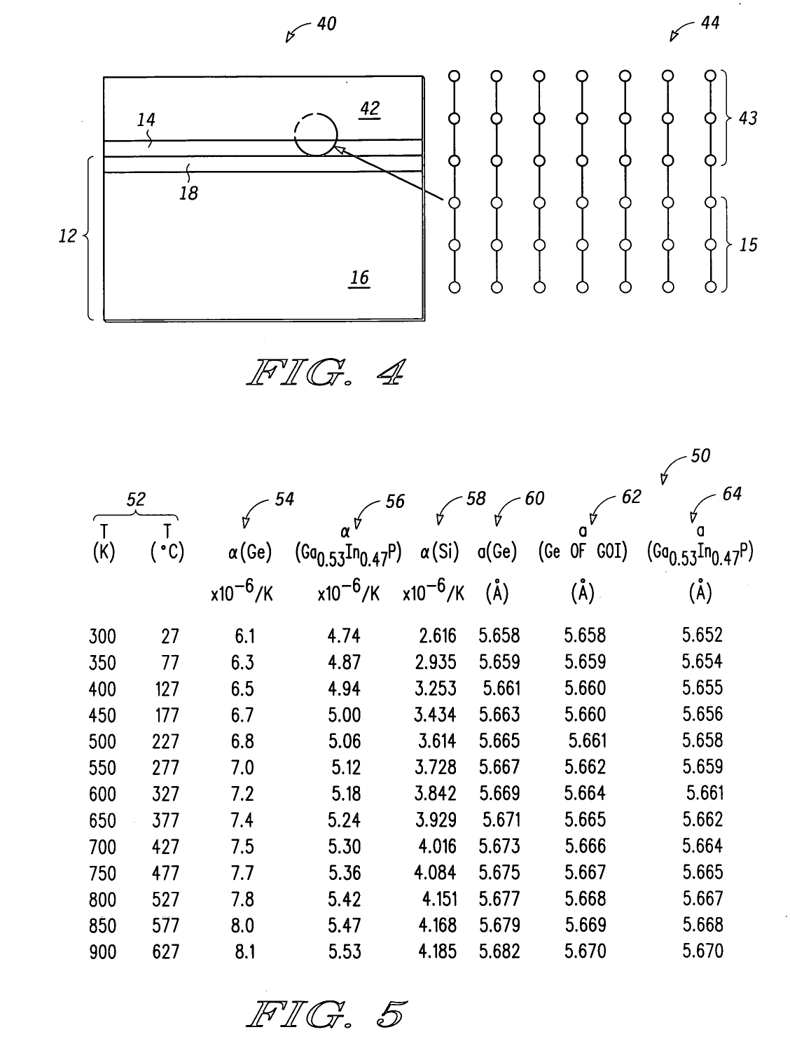

The use of the same reference symbols in different drawings indicates similar or identical items. Skilled artisans will also appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION

The embodiments of the present disclosure include selecting a III-V materials system for epitaxial growth on GOI that meets two criteria: (1) the CTE must be closer to Si; and (2) the material composition can be adjusted to match the silicon constrained Ge lattice constant at, or specifically slightly removed from, the growth temperature. In this regard, III-V alloys that have CTE's closer to Si and that can be lattice matched to constrained Ge include, for example, at least InGaP, InAlP, and GaAsP which are used in the industry. Other suitable III-V alloys may also exist. It is noted that at the low phosphorus (P) composition needed to lattice match constrained Ge, GaAsP will have a CTE close to GaAs and thus is not a good candidate. On the other hand, InGaP and InAlP have (with their quartemary AlGaInP) CTE's around 5E-6/K. Taking InGaP as an example, a lattice match at a 700 C growth temperature occurs for an indium composition of forty-seven percent (47%) and, with its estimated CTE, will have a tensile room temperature mismatch of about IE-3, about one-third (⅓) that of GaAs. Since the strain energy goes as the square of the mismatch, the InGaP film on GOI has approximately one-ninth ( 1/9) the tensile strain energy of the corresponding GaAs film. Thus, a properly chosen InGaP film of device thickness is expected to be stable on GOI and have low defectivity.

The method according to the embodiments of the present disclosure resolves several problems in a new way as follows. Epitaxial growth on GOI substrates with one-and-a-half percent (1.5%) InGaAs material showed high defectivity and began to show microcracks or delamination on GOI substrates at thicknesses approaching three (3) microns. It is believed that the new materials system according to the embodiments of the present disclosure, when properly tuned, will allow equivalent or greater epi thicknesses without delamination and will serve either as the buffer layer or as part of the active device layer for HBT's, LED's, lasers, detectors, and the like.

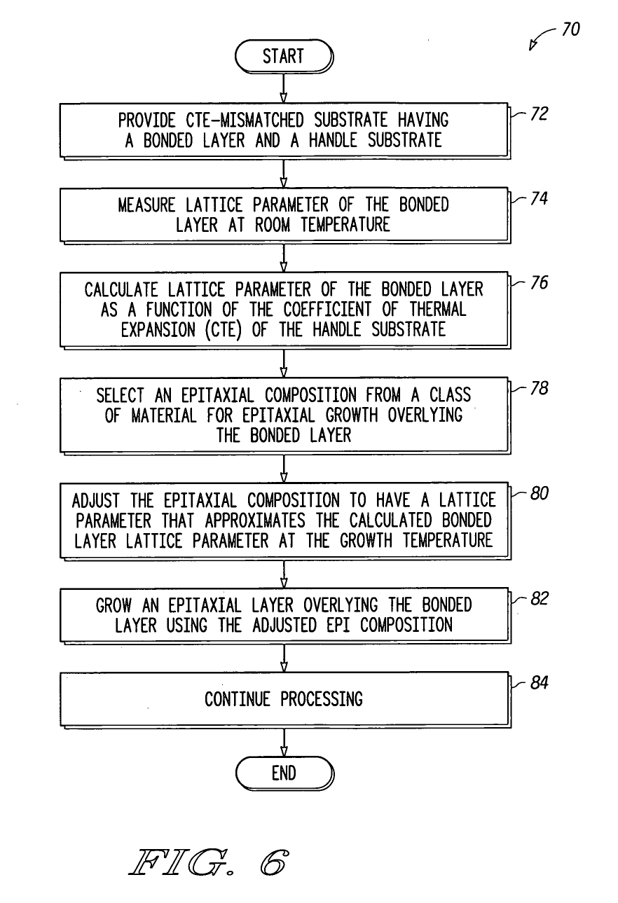

FIG. 4 is a cross-sectional view of a Ga_{0.53}In_{0.47}P epitaxial layer 42 grown on the GOI substrate 40 according to an embodiment of the present disclosure, wherein a lattice parameter of the Ga_{0.53}In_{0.47}P epitaxial layer 42 is correctly matched to a lattice parameter of the germanium 14 of the GOI substrate 40 at growth temperature. Ga_{0.53}In_{0.47} P epitaxial layer 42 is formed on the surface of germanium layer 14 using a metal organic chemical vapor deposition (MOCVD) process as is known in the art. In FIG. 4, reference numeral 15 generally indicates an illustration of the lattice and the bonds between atoms of the Ge layer 14. In addition, reference numeral 43 generally indicates an illustration of the lattice parameter and the bonds between atoms of the epitaxy layer 42. Note the absence of misfit dislocations within the epitaxy layer 42. In other words, there are no misfit dislocations that originate at an interface between the Ge layer 14 and epitaxy layer 42. The absence of misfit dislocations is due to a matching of the lattice parameter of the material of layer 42 with the lattice parameter of the constrained Ge of layer 14 during the growth process.

FIG. 5 is a table view 50 of various coefficients of thermal expansion (α) and lattice parameters (a) at various temperatures according to one embodiment of the present disclosure. The information contained in table 50 helps to explain how the embodiments of the present disclosure solve the problem encountered in growing a thick epi layer on GOI. Temperatures are indicated generally by reference numeral 52, presented in units of Kelvin (K) and degrees Celsius (° C.). Coefficients of thermal expansion (in units ×10⁻⁶/K) for Ge, Ga_{0.53}In_{0.47}P, and Si are generally indicated by reference numerals 54, 56, and 58, respectively. Lattice parameters (in Angstroms (Å)) for Ge, Ge of GOI, and Ga_{0.53}In_{0.47}P are generally indicated by reference numerals 60, 62, and 64, respectively. It is noted that at a temperature of 900 K, the lattice parameter 64 of Ga_{0.53}In_{0.47}P is matched to the lattice parameter 62 of the Ge of GOI. In other words, the Ga_{0.53}In_{0.47}P epitaxial layer comprises a material having a lattice parameter that approximates the lattice parameter of the bonded Ge layer at an epitaxial growth temperature of 900 K, which enables the growth of a low defect concentration epitaxial film. Then, as the substrate is cooled to room temperature, the relatively close match of the CTE's of Ga_{0.53}In_{0.47}P and Si results in reduced strain in the film, lessening defect formation or delamination risks. Similarly, temperature excursions during subsequent device processing are not likely to lead to defect formation or substrate delamination.

FIG. 6 is a flow diagram view of the method 70 of growing an epitaxial layer in the manufacturing of a semiconductor device according to an embodiment of the present disclosure. In an initial step 72, the method includes providing a CTE-mismatched substrate having a bonded layer and a handle substrate. In one embodiment, the CTE-mismatched substrate comprises a GOI substrate. In step 74, the method includes measuring a lattice parameter of the bonded layer at room temperature. In step 76, the method includes calculating the lattice parameter of the bonded layer as a function of the coefficient of thermal expansion of the handle substrate. Subsequently, the method includes selecting an epitaxial composition from a class of material for epitaxial growth overlying the bonded layer, in step 78. The most desired classes of materials are those with CTE's approximately similar to that of the handle substrate. The epitaxial composition is adjusted to have a lattice parameter that approximates the calculated bonded layer lattice parameter at the growth temperature, in step 80. The method next includes, in step 82, growing an epitaxial layer overlying the bonded layer using the adjusted epi composition. The method continues at step 84 with additional processing according to the requirements of a particular semiconductor device or integrated circuit application.

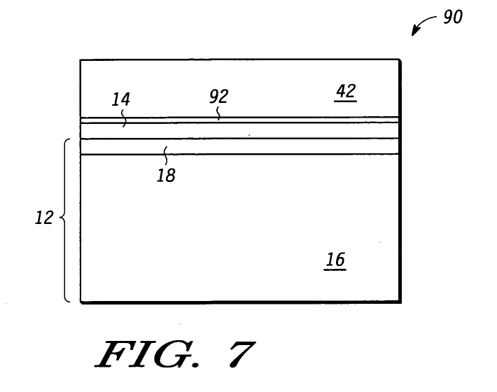

FIG. 7 is a cross-sectional cartoon view of an epitaxial layer 42 and nucleation layer 92 grown on the GOI substrate 90 according to another embodiment of the present disclosure, wherein a lattice parameter of the epitaxial layer 42 is correctly matched at the growth temperature to a lattice parameter of the germanium 14 of the GOI substrate 90.

Various process details, for example, nucleation sequence, growth conditions, etc., are selected in a manner so as to yield low defectivity, thick III-V epi layers on GOI substrates. In one embodiment, the process is chosen so as to demonstrate certain defectivity specifications (<1E5/cm²). Accordingly, the embodiments of the present disclosure provide a method for use to fully integrate III-V devices and silicon (or Ge) FETs into a integrated circuit product.

According to one embodiment of the present disclosure, a method for growing low defectivity thick III-V epi on Germanium on Insulator (GOI) substrates that will survive subsequent processing requires the selection of a material according to two criteria: (1) the CTE of the material must be as close as possible to Si, and (2) the material composition can be adjusted to match the silicon constrained Ge lattice constant at, or specifically slightly removed from, the growth temperature. Furthermore, the method according to the present embodiments enable growing of thick III-V epi on GOI substrates with low defectivity and stress levels sufficiently low to prevent delamination.

Three well known ternary III-V alloys that have CTE's closer to Si and that can be lattice matched to constrained Ge include InGaP, InAlP, and GaAsP. In one embodiment, InGaP is preferred and its composition can be varied to lattice match (i) bulk Ge, (ii) SiGe with a high Ge content, or (iii) constrained Ge on a GOI substrate. A lattice match at a 700 C growth temperature occurs for an indium composition of about forty-seven percent (47%) and, with its estimated CTE, will have a tensile room temperature mismatch of about 1E-3, about one-third (⅓) that of GaAs. A thick InGaP buffer layer can be grown either directly on the GOI Ge or upon a thin GaAs nucleation layer. In the later instance, the thin GaAs nucleation layer has a thickness below a critical thickness for the formation of dislocations.

In demonstrating a workability of the method according to the present embodiments, it is first noted that a calculated stress of InGaP and GaAs films is on the order of 146 MPa for InGaP and 257 MPa for GaAs. Wafer bow measurements of the stress of the InGaP films on GOI for several samples showed stress on the order of 92 MPa for a first sample, on the order of 130 MPa for a second sample, and on the order of 170 MPa for a third sample. In addition, an HBT structure was built in which the structure showed no presence of delamination.

Accordingly, the method of the present disclosure can be used to provide an optimized InGaP composition (i.e., depending on growth temperature), in addition to using a very thin optional GaAs layer as a nucleation layer, that can serve as a base material upon which to build III-V HBT, FET, or optoelectronic devices. In addition, the III-V epi layer on GOI substrate according to the embodiments of the present disclosure is of thickness sufficient for a corresponding III-V HBT, FET, or optoelectronic device(s).

The various embodiments of the present disclosure provide a broad materials platform that enables heterogeneous integration of III-V with silicon. The embodiments relate to III-V technology, and also to less than 90 nm silicon MOS integrated circuit devices and structures.

The embodiments of the present disclosure advantageously provide a materials platform to enable products which benefit from the monolithic integration of III-V devices with silicon. Such products may include one or more of the following:
a) High performance digital CMOS scaling through the use of GaAs MOS devices along a critical speed path and integrated alongside Si or Ge MOS devices.
b) Portable, wireless system integration through the integration of baseband and rf components on a single chip using a high resistivity Si substrate. This may include RF enabled by traditional GaAs and SiGe/Ge devices initially and by devices based on GaAs MOS technology.
c) Chip-to-chip optical communication. Portable systems utilizing separate stand-alone memory chip face a chip-to-chip data transfer bottleneck which could be solved with the integration of optical input/output integrated on the chips or IC's. Ge detectors and GaAs detectors, LEDs, and lasers are a few of the key components potentially enabled by this hetero-integration.
d) More advanced digital-photonic integration for higher system level functionality or other applications with a need for optical interconnects. Communications at terahertz frequencies will require improved and integrated optoelectronics and photonics.

According to one embodiment, the method includes choosing a III-V material that has two important attributes. In a first attribute, the III-V material must lattice match to the compressively strained Ge film of a GOI substrate at growth temperature (i.e., between 600 C and 740 C). With this first attribute, the film grows with low mismatch and thereby enables the formation of thick layers (as required for many III-V devices). In a second attribute, the III-V material must have a CTE as close as possible to the silicon handle wafer rather than Ge. With this second attribute, when cooled down, the tensile stress is minimized so that the corresponding films do not delaminate.

In one embodiment, InGaP is used as the III-V material. The InGaP material composition can be tuned to adjust the lattice parameter. In addition, estimating the InGaP CTE from the binary InP and GaP values suggests that the strain energy will be reduced by nearly an order of magnitude.

According to one embodiment, a method of forming crack-free III-V epitaxy on a germanium-on-insulator (GOI) substrate comprises: measuring a lattice parameter of the bonded layer at a first temperature; calculating the lattice parameter of the bonded layer as a function of a coefficient of thermal expansion (CTE) of the handle substrate at an epitaxial growth temperature, the epitaxial growth temperature being different from the first temperature; selecting an epitaxial composition from a class of III-V material for epitaxial growth overlying the bonded layer, wherein the selected epitaxial composition is adjusted to have a lattice parameter that approximates the calculated lattice parameter of the bonded layer at the epitaxy growth temperature; and growing the epitaxial layer over the bonded layer with use of the adjusted epitaxial composition.

In another embodiment, the GOI substrate includes a thin bonded layer and a thick handle substrate, wherein the bonded layer is constrained by the handle substrate. For example, the bonded layer can include germanium (Ge) and the handle substrate can include silicon (Si). In addition, the GOI substrate includes a coefficient of thermal expansion (CTE) mismatched substrate, wherein the grown epitaxial layer is lattice matched to silicon (Si) constrained germanium (Ge) at the epitaxy growth temperature. For example, the epitaxy growth temperature may include a temperature on the order of 900 K. In addition, the adjusted epitaxial composition can comprise, for example, Ga_{0.53}In_{0.47}P. Furthermore, the grown epitaxial layer may comprise Ga_{0.53}In_{0.47}P having a lattice parameter that approximates the lattice parameter of the bonded Ge layer at an epitaxial growth temperature of 900 K. The epitaxial growth temperature can also include a temperature in a range from 400° C. to 750° C. Still further, the method may comprise providing a nucleation layer over the bonded layer prior to growing the functional epitaxial layers.

In another embodiment, a method of forming III-V epitaxy comprises providing a coefficient of thermal expansion (CTE) mismatched substrate including (i) a handle substrate having a first coefficient of thermal expansion, and (ii) a bonded layer over the handle substrate, the bonded layer having a second coefficient of thermal expansion greater than the first coefficient of thermal expansion, the bonded layer further having a lattice parameter that is influenced by the handle substrate. A III-V epitaxial layer is grown over the bonded layer at an epitaxial growth temperature, wherein the epitaxial layer comprises a material composition adjusted for having a lattice parameter that approximates the lattice parameter of the bonded layer at the epitaxial growth temperature.

The epitaxial layer can comprise, for example, a material composition having been adjusted for lattice matching the bonded layer at the epitaxial growth temperature. The handle substrate can comprise, for example, at least one selected from the group consisting of silicon, glass, plastic, and sapphire. In addition, the bonded layer can comprise, for example, at least one selected from the group consisting of germanium and a compound semiconductor material. Alternatively, the bonded layer may comprise a first Group IV element compound, and the epitaxial layer may comprise a second Group III-V element compound. In one embodiment, the bonded layer comprises germanium and the epitaxial layer comprises indium gallium phosphide. In particular, the epitaxial layer can comprise Ga_{0.53}In_{0.47}P.

In addition, the CTE mismatched substrate can comprise, for example, a germanium-on-insulator (GOI) substrate. The bonded layer lattice parameter can be constrained by the handle substrate. Furthermore, the epitaxial layer can be characterized by a defectivity of less than 10⁵ defects/cm².

According to another embodiment, an apparatus comprises a substrate having a coefficient of thermal expansion (CTE) mismatch, wherein the substrate includes a handle substrate having a first coefficient of thermal expansion and a bonded layer over the handle substrate having a second coefficient of thermal expansion. The bonded layer further includes a lattice parameter that is influenced by the handle substrate. In addition, the apparatus includes an epitaxial layer over the bonded layer. The epitaxial layer comprises a material having a lattice parameter that approximates the lattice parameter of the bonded layer at an epitaxial growth temperature.

In one embodiment, the epitaxial growth temperature is a temperature in a range from 400° C. to 750° C. The handle layer comprises at least one material selected from the group consisting of silicon, glass, plastic, and sapphire. Alternatively, the bonded layer can comprise a first Group IV element compound. For example, the bonded layer may comprise one of germanium or a compound semiconductor. The epitaxial layer can comprise a second Group III-V element compound. In addition, the epitaxial layer can include a layer having a varying composition. In another embodiment, the bonded layer comprises germanium and the epitaxial layer comprises indium gallium phosphide.

In another embodiment, the handle substrate and the bonded layer are crystalline, however, the bonded layer has a lattice structure that is constrained by the handle substrate lattice structure as temperature is changed. In another embodiment, the epitaxial layer is a compound semiconductor. Furthermore, the epitaxial layer has a defect density of less than 10⁵ defects/cm² and there is not delamination or cracking of the epitaxy. In other words, the epitaxial layer is free of catastrophic defects. Catastrophic defects can include, for example, cracking or delamination of the bonded layer or the epitaxy layer from the handle substrate. Alternatively, the epitaxial layer exhibits a substantial absence of misfit dislocations.

In another embodiment, a method of growing an epitaxial layer over a multi-layer substrate includes providing a handle substrate with a first coefficient of thermal expansion and a second layer with a second coefficient of thermal expansion bonded to the handle substrate. The method further includes measuring a first lattice parameter of the second layer at a first temperature and calculating a second lattice parameter of the second layer at a second temperature. The second lattice parameter at the second temperature is a function of the first coefficient of thermal expansion and the first lattice parameter. Upon calculating the second lattice parameter of the second layer at the second temperature, the method includes adjusting a composition of epitaxial layer to have a lattice parameter that approximates the second lattice parameter and growing the epitaxial layer using the adjusted composition. Furthermore, the method includes selecting an epitaxial composition from a plurality of available epitaxial compositions which has a coefficient of thermal expansion closest to the first coefficient of thermal expansion. In another embodiment, the method includes providing the handle substrate and the second layer, wherein the second layer is physically coupled to the handle substrate via an insulating layer.

In yet another embodiment, the step of measuring a lattice parameter can comprise using x-ray diffraction. In addition, calculating the lattice parameter can include: (i) averaging the coefficient of thermal expansion from the first temperature to the second temperature, or (ii) integrating the coefficient of thermal expansion from the first temperature to the second temperature.

In other embodiments, other candidate III-V materials may be possible. Also, one may choose the lattice constant slightly mismatched so as to grow the III-V epi slightly compressive at growth temperature (but not so compressive that the film will relax for a given thickness) which will further reduce the tensile strain at room temperature.

The embodiments of the present disclosure solve problems and issues faced in the growing III-V epi on GOI, such as GaAs on GOI, which has not previously been known.

In the foregoing specification, the disclosure has been described with reference to various embodiments. However, one of ordinary skill in the art appreciates that various modifications and changes can be made without departing from the scope of the present embodiments as set forth in the claims below. Accordingly, the specification and figures are to be regarded in an illustrative rather than a restrictive sense, and all such modifications are intended to be included within the scope of the present embodiments. For example, the present embodiments can apply to semiconductor device technologies where minimal defectivity is crucial to the device performance.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the term “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method of forming III-V epitaxy on a germanium-on-insulator (GOI) substrate, the GOI substrate including a bonded layer and a handle substrate, wherein the GOI substrate comprises a coefficient of thermal expansion (CTE) mismatched substrate, wherein the bonded layer is constrained by the handle substrate, the method comprising:
measuring a lattice parameter of the bonded layer at a first temperature;
calculating the lattice parameter of the bonded layer as a function of a coefficient of thermal expansion (CTE) of the handle substrate at an epitaxial growth temperature, the epitaxial growth temperature being different from the first temperature;
selecting an epitaxial composition from a class of III-V material for epitaxial growth overlying the bonded layer, wherein the class of III-V material is selected to have a coefficient of thermal expansion approximately similar to that of the handle substrate and the selected epitaxial composition is adjusted to have a lattice parameter that approximates the calculated lattice parameter of the bonded layer at the epitaxial growth temperature; and
growing an epitaxial layer over the bonded layer with use of the adjusted epitaxial composition.

2. The method of claim 1, wherein the bonded layer comprises germanium (Ge).

3. The method of claim 1, wherein the handle substrate comprises one selected from the group consisting of silicon (Si), glass, plastic, and sapphire.

4. The method of claim 1, wherein the epitaxial layer is lattice matched to silicon (Si) constrained germanium (Ge) at the epitaxial growth temperature.

5. The method of claim 1, wherein the epitaxial growth temperature comprises a temperature on the order of 900 K.

6. The method of claim 1, wherein the adjusted epitaxial composition comprises Ga_{0.53}In_{0.47}P.

7. The method of claim 1, wherein the epitaxial layer comprises Ga_{0.53}In_{0.47}P having a lattice parameter that approximates the lattice parameter of a bonded Ge layer at an epitaxial growth temperature of 900 K.

8. The method of claim 1, wherein the epitaxial growth temperature is a temperature in a range from 400° C. to 750° C.

9. The method of claim 1, further comprising:
providing a nucleation layer over the bonded layer prior to growing the epitaxial layer.

10. A method of forming III-V epitaxy comprising:
providing a coefficient of thermal expansion (CTE) mismatched substrate including (i) a handle substrate having a first coefficient of thermal expansion, and (ii) a bonded layer over the handle substrate, the bonded layer having a second coefficient of thermal expansion different from the first coefficient of thermal expansion, the bonded layer further having a lattice parameter that is influenced by the handle substrate; and
growing a III-V epitaxial layer over the bonded layer at an epitaxial growth temperature, wherein the epitaxial layer comprises a material composition adjusted for having a lattice parameter that approximates the lattice parameter of the bonded layer at the epitaxial growth temperature and to have a coefficient of thermal expansion approximately similar to that of the handle substrate.

11. The method of claim 10, wherein the epitaxial layer comprises a material composition having been adjusted for lattice matching the bonded layer at the epitaxial growth temperature.

12. The method of claim 10, wherein the handle substrate comprises at least one selected from the group consisting of silicon, glass, plastic, and sapphire.

13. The method of claim 10, wherein the bonded layer comprises at least one selected from the group consisting of germanium and a compound semiconductor material.

14. The method of claim 10, wherein the bonded layer comprises a first Group IV element compound, and the epitaxial layer comprises a second Group III-V element compound.

15. The method of claim 10, wherein the bonded layer comprises germanium and the epitaxial layer comprises indium gallium phosphide.

16. The method of claim 15, further wherein the epitaxial layer comprises Ga_{0.53}In_{0.47}P.

17. The method of claim 10, wherein the CTE mismatched substrate comprises a germanium-on-insulator (GOI) substrate.

18. The method of claim 10, wherein the bonded layer lattice parameter is constrained by the handle substrate.

19. The method of claim 10, wherein the epitaxial layer is characterized by a defectivity of less than 10⁵ defects/cm².

20. A semiconductor device including an epitaxial layer formed by the method of claim 10.

21. The method of claim 10, further comprising: providing a nucleation layer over the bonded layer prior to growing the epitaxial layer.
